(19) United States
(12) Patent Application Publication
(10) Pub. No.: US 2026/0107852 A1
(43) Pub. Date: Apr. 16, 2026

(54) SEMICONDUCTOR DEVICE

(71) Applicant: SHINKO ELECTRIC INDUSTRIES CO., LTD., Nagano-shi (JP)

(72) Inventor: Shinichiro Sekijima, Nagano (JP)

(21) Appl. No.: 19/353,746

(22) Filed: Oct. 9, 2025

(30) Foreign Application Priority Data
Oct. 15, 2024 (JP) 2024-179675

(51) Int. Cl. H01L 23/498; H01L 21/48; H01L 23/00

(52) U.S. Cl. CPC H10W 90/701; H10W 70/093; H10W 90/401; H10W 74/15; H10W 90/724; H10W 90/735

(57) ABSTRACT

A semiconductor device includes a first wiring board , an electronic component, a second wiring board, a plurality of connection members, and a sealing resin. The electronic component is arranged on the first wiring board. The second wiring board is arranged on the first wiring board so as to sandwich the electronic component. The plurality of connection members connect the first wiring board and the second wiring board. The first wiring board includes a first pad that is connected to a connection member that is located arround the electronic component among the plurality of connection members, and the second wiring board includes a second pad that is connected to the connection member located arround the electronic component and that is placed offset from the first pad in a direction that intersects a lamination direction of the first wiring board and the second wiring board.

### CROSS-REFERENCE TO RELATED APPLICATION

This application is based upon and claims the benefit of priority of the prior Japanese Patent Application No. 2024-179675, filed on October 15, 2024, the entire contents of which are incorporated herein by reference.

### FIELD

The embodiment discussed herein is related to a semiconductor device.

### BACKGROUND

In recent years, to realize high-density component mounting, for example, a semiconductor device in which an electronic component, such as a semiconductor chip, is incorporated in a substrate is attracting attention. The semiconductor device as described above includes, for example, two wiring boards, where an electronic component, such as a semiconductor chip, is mounted on one of the wiring boards and the electronic component is sandwiched between the wiring board and a different organic substrate. The two wiring boards are connected by a plurality of connection members, such as solders, for example. Further, a space between the two wiring boards is filled with, for example, a sealing resin.

In this manner, by incorporating the electronic component between the two wiring boards, it is possible to realize three-dimensional component mounting, so that it is possible to realize densification and downsizing of a semiconductor device.

Patent Literature 1: Japanese Patent No. 4182140

However, in the semiconductor device in which the electronic component is incorporated, there is a problem in that void occurs in the sealing resin that is filled in the space between the two wiring boards that sandwich the electronic component.

Specifically, the plurality of connection members for connecting the two wiring boards are located arround the electronic component, and therefore, the sealing resin that is filled in the space between the two wiring boards flows into a space between the electronic component and the wiring board that faces the electronic component through a gap between the connection members. However, the space between the electronic component and the wiring board is relatively small and flowability of the sealing resin easily decreases. Therefore, in particular, when widths of the connection members that are located arround the electronic component are relatively large, a gap between the connection members is reduced, so that the flowability of the sealing resin decreases arround the electronic component while the sealing resin is filled in the space between the two wiring boards. As a result, void easily occurs in the sealing resin.

### SUMMARY

According to an aspect of an embodiment, a semiconductor device includes a first wiring board; an electronic component that is mounted on the first wiring board; a second wiring board that is laminated on the first wiring board so as to sandwich the electronic component; a plurality of connection members that connect the first wiring board and the second wiring board; and a sealing resin that is filled in a space between the first wiring board and the second wiring board, and covers the electronic component and the plurality of connection members, wherein the first wiring board includes a first pad that is connected to a connection member that is located arround the electronic component among the plurality of connection members, and the second wiring board includes a second pad that is connected to the connection member located arround the electronic component and that is placed offset from the first pad in a direction that intersects a lamination direction of the first wiring board and the second wiring board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a semiconductor device according to one embodiment;

FIG. 2 is a schematic cross-sectional view of the semiconductor device according to one embodiment taken along a plan that intersects a lamination direction;

FIG. 3 is a flowchart illustrating a method of manufacturing a first wiring board according to one embodiment;

FIG. 4 is a schematic diagram illustrating a cross section of the first wiring board;

FIG. 5 is a diagram for explaining mounting of an electronic component;

FIG. 6 is a diagram illustrating a specific example of a solder ball mounting process;

FIG. 7 is a flowchart illustrating a method of manufacturing a second wiring board according to one embodiment;

FIG. 8 is a schematic diagram illustrating a cross section of the second wiring board;

FIG. 9 is a diagram illustrating a specific example of a solder ball mounting process;

FIG. 10 is a flowchart illustrating a method of manufacturing the semiconductor device according to one embodiment;

FIG. 11 is a diagram for explaining lamination of the first wiring board and the second wiring board;

FIG. 12 is a diagram illustrating a specific example of a bonding process;

FIG. 13 is a diagram illustrating a specific example of a molding process;

FIG. 14 is a diagram illustrating a specific example of a singulation process; and

FIG. 15 is a diagram illustrating a configuration of a semiconductor device according to a modification of one embodiment.

### DESCRIPTION OF EMBODIMENT

Embodiment of a semiconductor device disclosed in the present application will be described in detail below based on the drawings. Meanwhile, the disclosed technology is not limited by the embodiment below.

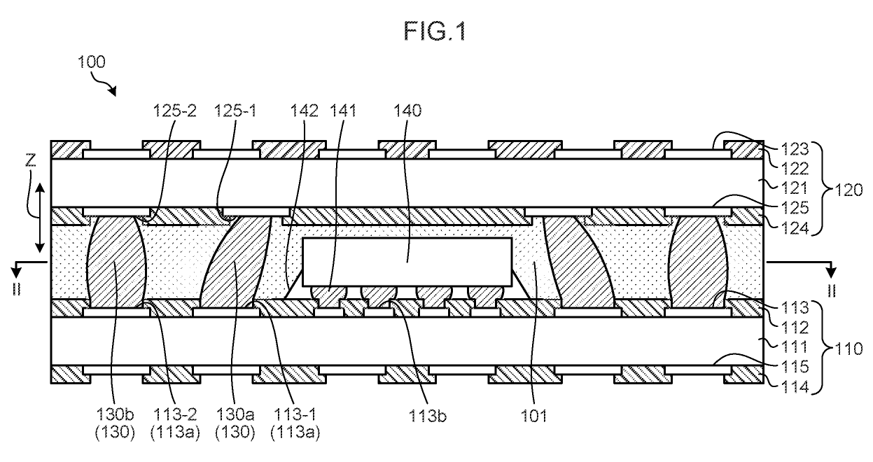

FIG. 1 is a diagram illustrating a configuration of a semiconductor device 100 according to one embodiment. FIG. 1 schematically illustrates a cross section of the semiconductor device 100. Meanwhile, in the following, for the sake of convenience, a direction from a first wiring board 110 to a second wiring board 120 is referred to as an upward direction, a direction from the second wiring board 120 to the first wiring board 110 is referred to as a downward direction, and a vertical direction of the semiconductor device 100 is defined based on the upward direction and the downward direction. However, for example, the semiconductor device 100 may be manufactured and used upside down, and may be manufactured and used in an arbitrary posture.

The semiconductor device 100 illustrated in FIG. 1 includes the first wiring board 110 and the second wiring board 120, and includes a sealing resin 101 that covers an electronic component 140 that is arranged so as to be sandwiched between the first wiring board 110 and the second wiring board 120. Specifically, the semiconductor device 100 is configured by connecting the first wiring board 110 and the second wiring board 120 by a plurality of connection members 130. Further, the electronic component 140 is mounted on an upper surface of the first wiring board 110, and the electronic component 140 is sandwiched between the first wiring board 110 and the second wiring board 120 and covered by the sealing resin 101.

The sealing resin 101 is, for example, an insulating resin, such as a thermosetting epoxy resin, that contains an inorganic filler, such as alumina, silica, aluminum nitride, or silicon carbide. The electronic component 140 is, for example, a semiconductor chip.

The first wiring board 110 includes a substrate 111, a protective insulating layer 112 (one example of a first insulating layer), upper pads 113, a solder resist layer 114, and lower pads 115. Meanwhile, although illustration is omitted in FIG. 1, the upper pads 113 and the lower pads 115 are electrically connected to each other by via wiring that is arranged in the substrate 111.

The substrate 111 is an insulating plate-shaped member and a base material of the first wiring board 110. As a material of the substrate 111, for example, a glass epoxy resin, in which a glass cloth (glass woven fabric) as a reinforcing material is impregnated with a thermosetting insulating resin that is mainly composed of an epoxy resin, or the like may be used. The reinforcing material is not limited to the glass cloth, but may be, for example, a glass non-woven fabric, an aramid woven fabric, an aramid non-woven fabric, a Liquid Crystal Polymer (LCP) woven fabric, an LCP non-woven fabric, or the like. Further, as the thermosetting insulating resin, for example, a polyimide resin, a cyanate resin, or the like may be used, instead of the epoxy resin. Wiring layers including the upper pads 113 and the lower pads 115 are formed on both surfaces of the substrate 111. As a material of the wiring layers, for example, copper or copper alloy may be used.

Meanwhile, the substrate 111 is not limited to a single-layer insulating member, but may be a multilayer substrate that has a multilayer structure in which an insulating layer and a wiring layer are laminated. When the substrate 111 is a multilayer substrate, wiring layers that sandwich an insulating layer are electrically connected to each other by a via that penetrates through the insulating layer. As a material of the insulating layer, for example, an insulating resin, such as an epoxy resin or a polyimide resin, or a resin material that is a mixture of a resin and a filler, such as silica or alumina, may be used. Further, as a material of the wiring layers, for example, copper (Cu) or copper alloy may be used.

The protective insulating layer 112 is an insulating layer that covers an upper surface of the substrate 111. Opening portions are arranged in parts of the protective insulating layer 112, and the upper pads 113 are exposed from the opening portions. As a material of the protective insulating layer 112, for example, an insulating resin, such as an epoxy-type resin or an acrylic-type resin, may be used.

The upper pads 113 are formed on the wiring layer on the upper surface of the substrate 111, and are exposed from the opening portions of the protective insulating layer 112 so as to connect to the connection members 130 and mount the electronic component 140. Specifically, the connection members 130 are connected to upper pads 113a of the upper pads 113. The upper pads 113a include an inner pad 113-1 (one example of a first pad) and an outer pad 113-2. The inner pad 113-1 is connected to a connection member 130a that is located arround the electronic component 140 among the plurality of connection members 130, and the outer pad 113-2 is connected to a connection member 130b that is located farther from the electronic component 140 than the connection member 130a. Further, upper pads 113b of the upper pads 113 are connected to the electronic component 140. Specifically, for example, the electronic component 140 is flip-chip connected to the upper pads 113b by solder bumps 141. Furthermore, a space between the first wiring board 110 and the electronic component 140 is filled with an underfill material 142. As a material of the upper pads 113, similarly to the wiring layer, for example, copper or copper alloy may be used.

The solder resist layer 114 is an insulating layer that covers a lower surface of the substrate 111. Opening portions are arranged in parts of the solder resist layer 114, and the lower pads 115 are exposed from the opening portions. As a material of the solder resist layer 114, for example, an insulating resin, such as an epoxy-type resin or an acrylic-type resin, may be used.

The lower pads 115 are formed on the wiring layer on the lower surface of the substrate 111, and are exposed from the opening portions of the solder resist layer 114 so as to form external connecting terminals. Specifically, external connecting terminals (not illustrated), such as solder balls, are formed on the lower pads 115, for example. As a material of the lower pads 115, similarly to the wiring layer, for example, copper or copper alloy may be used.

The second wiring board 120 includes a substrate 121, a solder resist layer 122, upper pads 123, a protective insulating layer 124 (one example of a second insulating layer), and lower pads 125. Meanwhile, although illustration is omitted in FIG. 1, the upper pads 123 and the lower pads 125 are electrically connected to each other by via wiring that is arranged in the substrate 121.

The substrate 121 is an insulating plate-shaped member and a base material of the second wiring board 120. As a material of the substrate 121, for example, a glass epoxy resin, in which a glass cloth (glass woven fabric) as a reinforcing material is impregnated with a thermosetting insulating resin that is mainly composed of an epoxy resin, or the like may be used. The reinforcing material is not limited to the glass cloth, but may be, for example, a glass non-woven fabric, an aramid woven fabric, an aramid non-woven fabric, an LCP fabric, an LCP non-woven fabric, or the like. Further, as the thermosetting insulating resin, for example, a polyimide resin, a cyanate resin, or the like may be used, instead of the epoxy resin. Wiring layers including the upper pads 123 and the lower pads 125 are formed on both surfaces of the substrate 121. As a material of the wiring layers, for example, copper or copper alloy may be used.

Meanwhile, the substrate 121 is not limited to a single-layer insulating member, but may be a multilayer substrate that has a multilayer structure in which an insulating layer and a wiring layer are laminated. When the substrate 121 is a multilayer substrate, wiring layers that sandwich an insulating layer are electrically connected to each other by a via that penetrates through the insulating layer. As a material of the insulating layer, for example, an insulating resin, such as an epoxy resin or a polyimide resin, or a resin material that is a mixture of a resin and a filler, such as silica or alumina, may be used. Further, as a material of the wiring layers, for example, copper (Cu) or copper alloy may be used.

The solder resist layer 122 is an insulating layer that covers an upper surface of the substrate 121. Opening portions are arranged in parts of the solder resist layer 122, and the upper pads 123 are exposed from the opening portions. As a material of the solder resist layer 122, for example, an insulating resin, such as an epoxy-type resin or an acrylic-type resin, may be used.

The upper pads 123 are formed on the wiring layer on the upper surface of the substrate 121, and are exposed from the opening portions of the solder resist layer 122 so as to form external connecting terminals. Specifically, external connecting terminals (not illustrated), such as solder balls, are formed on the upper pads 123. As a material of the upper pads 123, similarly to the wiring layer, for example, copper or copper alloy may be used.

The protective insulating layer 124 is an insulating layer that covers a lower surface of the substrate 121. Opening portions are arranged in parts of the protective insulating layer 124, and the lower pads 125 are exposed from the opening portions. As a material of the protective insulating layer 124, for example, an insulating resin, such as an epoxy-type resin or an acrylic-type resin, may be used.

The lower pads 125 are formed on the wiring layer on the lower surface of the substrate 121, and are exposed from the opening portions of the protective insulating layer 124 so as to connect to the connection members 130. Specifically, the connection members 130 are bonded to the lower pads 125. The lower pads 125 include an inner pad 125-1 (one example of a second pad) and an outer pad 125-2. The inner pad 125-1 is connected to the connection member 130a that is located arround the electronic component 140 among the plurality of connection members 130, and the outer pad 125-2 is connected to the connection member 130b that is located farther from the electronic component 140 than the connection member 130a. As a material of the lower pads 125, similarly to the wiring layer, for example, copper or copper alloy may be used.

In one embodiment, the inner pad 125-1 that is connected to the connection member 130a is placed offset from the inner pad 113-1 that is similarly connected to the connection member 130a, in a direction that intersects a lamination direction Z of the first wiring board 110 and the second wiring board 120. Specifically, the inner pad 125-1 is placed offset from the inner pad 113-1 in a direction that intersects the lamination direction Z and that approaches the electronic component 140.

In this manner, in one embodiment, the inner pad 125-1 that is connected to one end of the connection member 130a arround the electronic component 140 is placed offset from the inner pad 113-1 that is connected to another end of the connection member 130a, in the direction that intersects the lamination direction Z. With this configuration, a straight-line distance of the connection member 130a that connects a center of the inner pad 125-1 and a center of the inner pad 113-1 is increased as compared to a straight-line distance of the connection member 130b that connects a center of the outer pad 125-2 and a center of the outer pad 113-2. Therefore, a drawing amount of the connection member 130a between the inner pad 125-1 and the inner pad 113-1 is increased as compared to a drawing amount of the connection member 130b between the outer pad 125-2 and the outer pad 113-2, so that it is possible to reduce a width of the connection member 130a. By reducing the width of the connection member 130a, a gap between the adjacent connection members 130a is increased, so that flowability of the sealing resin 101 arround the electronic component 140 is improved when the sealing resin 101 is filled in the space between the first wiring board 110 and the second wiring board 120. With this configuration, it is possible to allow the sealing resin 101 to smoothly flow into a relatively narrow space between the electronic component 140 and the first wiring board 110, so that it is possible to prevent occurrence of void in the sealing resin 101.

Furthermore, the inner pad 125-1 is placed offset from the inner pad 113-1 in the direction that intersects the lamination direction Z and that approaches the electronic component 140. With this configuration, it is possible to draw the connection member 130a in the direction that approaches the electronic component 140 between the inner pad 125-1 and the inner pad 113-1. Therefore, arround the electronic component 140, it is possible to boost flow of the sealing resin 101 to the electronic component 140, so that it is possible to further prevent occurrence of void in the sealing resin 101.

The plurality of connection members 130 are formed of, for example, solders or the like, and connect the first wiring board 110 and the second wiring board 120. Specifically, each of the connection members 130 is an integrated body in which a solder ball that is mounted on the first wiring board 110 and a solder ball that is mounted on the second wiring board 120 are integrated. Each of the connection members 130 has a barrel shape in which a width of a lower end that is connected to the first wiring board 110 is larger than a width of an upper end that is connected to the second wiring board 120 such that side surfaces are bulged outward.

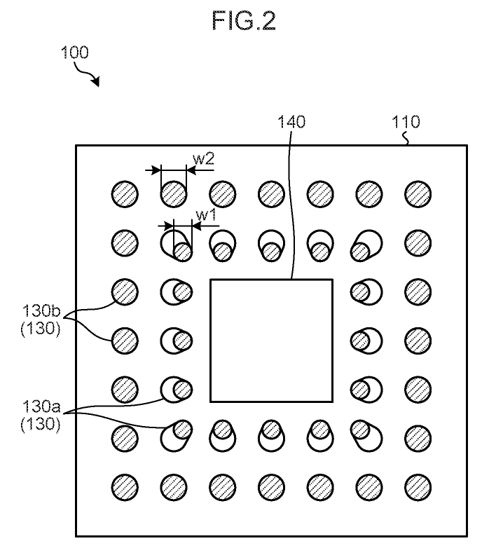

FIG. 2 is a schematic cross-sectional view of the semiconductor device 100 according to one embodiment taken along a plane that intersects the lamination direction Z. FIG. 2 corresponds to a cross section of the semiconductor device 100 taken along a line II-II in FIG. 1. Meanwhile, in FIG. 2, for the sake of simplicity of explanation, illustration of the sealing resin 101 is omitted.

As illustrated in FIG. 2, the plurality of connection members 130 have different widths in the direction that intersects the lamination direction Z (see FIG. 1), in accordance with a relative position with respect to the electronic component 140. Specifically, the connection members 130a that are located arround the electronic component 140 have smaller widths than the connection members 130b (one example of a different connection member) that are located farther from the electronic component 140 than the connection members 130a, in the direction that intersects the lamination direction Z. In other words, a width w1 of the connection member 130a in the direction that intersects the lamination direction Z is smaller than a width w2 of the connection member 130b in the direction that intersects the lamination direction Z. For example, in an upper part of the connection members 130a and 130b relative to a central part in the lamination direction Z, the width w1 of the connection member 130a is smaller than the width w2 of the connection member 130b.

The width w1 of the connection member 130a is smaller than the width w2 of the connection member 130b, so that it is possible to widen a gap between the adjacent connection members 130a as compared to a gap between the adjacent connection members 130b. Therefore, it is possible to improve the flowability of the sealing resin 101 arround the electronic component 140 when the sealing resin 101 is filled in the space between the first wiring board 110 and the second wiring board 120. With this configuration, it is possible to allow the sealing resin 101 to smoothly flow into a relatively narrow space between the electronic component 140 and the first wiring board 110, so that it is possible to prevent occurrence of void in the sealing resin 101.

A method of manufacturing the semiconductor device 100 that is configured as described above will be described below. In the following, a method of manufacturing the first wiring board 110 and a method of manufacturing the second wiring board 120 will be first described, and thereafter, a method of manufacturing the semiconductor device 100 that includes the first wiring board 110 and the second wiring board 120 will be described.

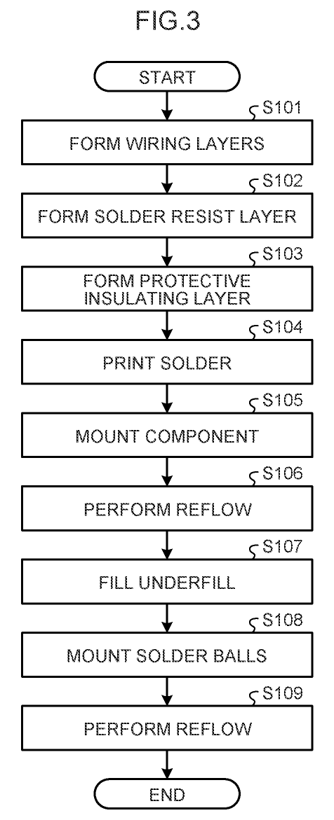

FIG. 3 is a flowchart illustrating the method of manufacturing the first wiring board 110 according to one embodiment.

Firstly, wiring layers are formed on the upper surface and the lower surface of the substrate 111 (Step S101). Specifically, the wiring layers on the upper surface and the lower surface of the substrate 111 are sequentially formed by, for example, a semi-additive process. The wiring layer on the upper surface of the substrate 111 includes the upper pads 113, and the wiring layer on the lower surface of the substrate 111 includes the lower pads 115. Further, the solder resist layer 114 that includes the opening portions at the positions of the lower pads 115 is formed on the lower surface of the substrate 111 (Step S102), and the protective insulating layer 112 that includes the opening portions at the positions of the upper pads 113 is formed on the upper surface of the substrate 111 (Step S103). The protective insulating layer 112 and the solder resist layer 114 are obtained by, for example, laminating a photosensitive resin film or applying a liquid or paste resin on the upper surface and the lower surface of the substrate 111, exposing and developing the laminated or applied resin by a photolithography method, and performing patterning to obtain a predetermined shape.

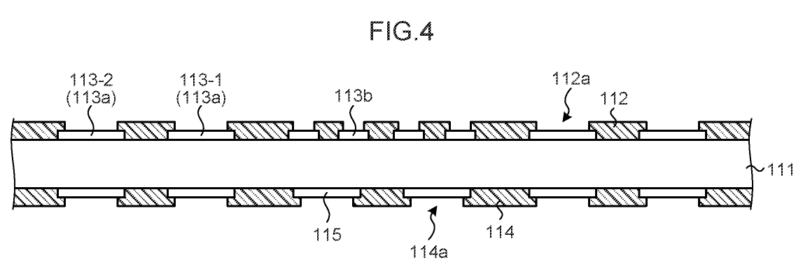

Through the process as described above, for example, as illustrated in FIG. 4, the first wiring board 110 is formed in which the upper pads 113a and 113b are exposed from opening portions 112a of the protective insulating layer 112 on the upper surface of the substrate 111 and the lower pads 115 are exposed from opening portions 114a of the solder resist layer 114 on the lower surface of the substrate 111. FIG. 4 is a schematic diagram illustrating a cross section of the first wiring board. The upper pads 113a are pads that are connected to the connection members 130, and include the inner pad 113-1 and the outer pad 113-2. The inner pad 113-1 is a pad that is connected to the connection member 130a that is located arround the electronic component 140 among the plurality of connection members 130, and the outer pad 113-2 is a pad that is connected to the connection member 130b that is located farther from the electronic component 140 than the connection member 130a. The upper pads 113b are pads that are flip-chip connected to the electronic component 140. Areas in which the upper pads 113a and 113b are exposed may be different from each other. Furthermore, a width of a portion from which each of the upper pads 113a is exposed may be set to, for example, about 120 micrometers (μm) to 160 μm.

A solder paste is printed on the upper pads 113b so as to mount the electronic component 140 (Step S104). Further, the electronic component 140 is mounted at the positions of the upper pads 113b (Step S105). The electronic component 140 is subjected to a reflow process (Step S106), and mounted on the first wiring board 110. Furthermore, if needed, the underfill material 142 that is made of an insulating resin is filled in a space between the electronic component 140 and the upper surface of the first wiring board 110 (Step S107).

The electronic component 140 is mounted on the upper surface of the first wiring board 110, and the upper surface of the first wiring board 110 arround the electronic component 140 is covered by the underfill material 142; therefore, a degree of freedom in placement of the upper pads 113a is lower than the inner pad 125-1 to be described later.

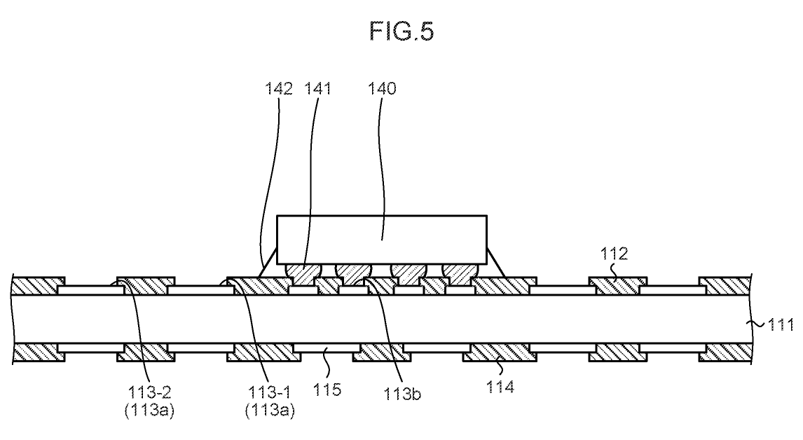

Through the process as described above, for example, as illustrated in FIG. 5, the electronic component 140 that is flip-chip connected to the upper pads 113b by the solder bumps 141 is mounted on the upper surface of the first wiring board 110. FIG. 5 is a diagram for explaining mounting of the electronic component 140.

When the electronic component 140 is mounted on the upper surface of the first wiring board 110, solder balls 131 that are used to form the connection members 130 are mounted at the positions of the upper pads 113a (Step S108). Then, by performing a reflow process (Step S109), the solder balls 131 are bonded to the upper pads 113a.

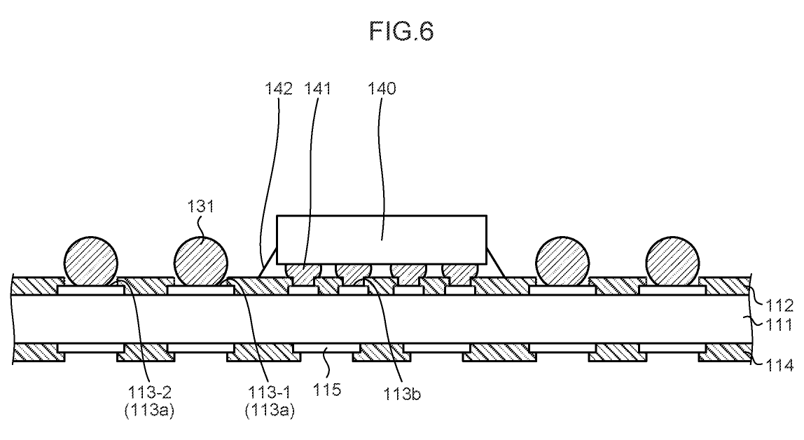

Through the process as described above, for example, as illustrated in FIG. 6, the solder balls 131 (one example of a first conductor ball) are bonded to the upper pads 113a. With this configuration, the first wiring board 110 that forms a lower layer of the semiconductor device 100 is obtained. FIG. 6 is a diagram illustrating a specific example of a solder ball mounting process. On the upper surface of the obtained first wiring board 110, the electronic component 140 is mounted and the solder balls 131 are bonded to the upper pads 113a that are exposed from the opening portions of the protective insulating layer 112. A diameter of each of the solder balls 131 may be set to, for example, about 100 μm to 250 μm.

Meanwhile, it is preferable to manufacture the first wiring board 110 as an assembly in which the plurality of first wiring boards 110 are arrayed, instead of manufacturing the first wiring board 110 as a single unit. In the assembly, for example, the first wiring board 110 is manufactured in an individual section that is a divided grid.

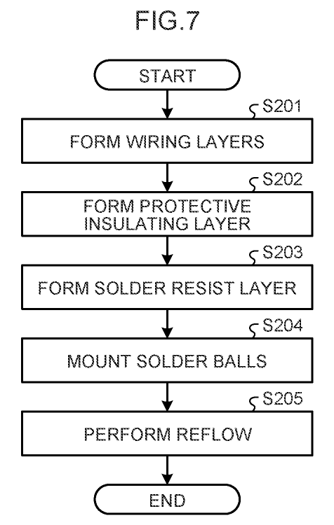

FIG. 7 is a flowchart illustrating the method of manufacturing the second wiring board 120 according to one embodiment.

Firstly, wiring layers are formed on the upper surface and the lower surface of the substrate 121 (Step S201). Specifically, the wiring layers on the upper surface and the lower surface of the substrate 121 are sequentially formed by, for example, a semi-additive process. The wiring layer on the upper surface of the substrate 121 includes the upper pads 123, and the wiring layer on the lower surface of the substrate 121 includes the lower pads 125. Further, the protective insulating layer 124 that includes the opening portions at the positions of the lower pads 125 is formed on the lower surface of the substrate 121 (Step S202), and the solder resist layer 122 that includes the opening portions at the positions of the upper pads 123 is formed on the upper surface of the substrate 121 (Step S203). The solder resist layer 122 and the protective insulating layer 124 are obtained by, for example, laminating a photosensitive resin film or applying a liquid or paste resin on the upper surface and the lower surface of the substrate 121, exposing and developing the laminated or applied resin by a photolithography method, and performing patterning to obtain a predetermined shape.

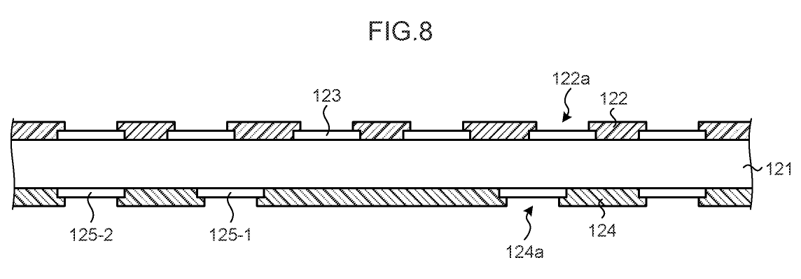

Through the process as described above, for example, as illustrated in FIG. 8, the second wiring board 120 is formed in which the upper pads 123 are exposed from opening portions 122a of the solder resist layer 122 on the upper surface of the substrate 121 and the lower pads 125 are exposed from opening portions 124a of the protective insulating layer 124 on the lower surface of the substrate 121. FIG. 8 is a schematic diagram illustrating a cross section of the second wiring board. The lower pads 125 are pads that are connected to the connection members 130, and include the inner pad 125-1 and the outer pad 125-2. The inner pad 125-1 is a pad that is connected to the connection member 130a that is located arround the electronic component 140 among the plurality of connection members 130, and the outer pad 125-2 is a pad that is connected to the connection member 130b that is located farther from the electronic component 140 than the connection member 130a.

Furthermore, the inner pad 125-1 is placed offset from the inner pad 113-1 in the direction that intersects the lamination direction Z (see FIG. 1). The opening portions 124a of the protective insulating layer 124 are placed offset from the opening portions 112a of the protective insulating layer 112 in the direction that intersects the lamination direction Z. With this configuration, it is possible to keep the area of the inner pad 125-1 that is exposed from the opening portion 124a of the protective insulating layer 124 to a certain area that is suitable for connection to the connection member 130a that is located arround the electronic component 140.

A degree of freedom in placement of the inner pad 125-1 is higher than the upper pads 113a, and therefore, the inner pad 125-1 can be placed offset in a relatively flexible direction.

The lower pads 125 are connected to the connection members 130, and therefore, solder balls 132 that are used to form the connection members 130 are mounted at the positions of the lower pads 125 (Step S204). Then, by performing a reflow process (Step S205), the solder balls 132 are bonded to the lower pads 125.

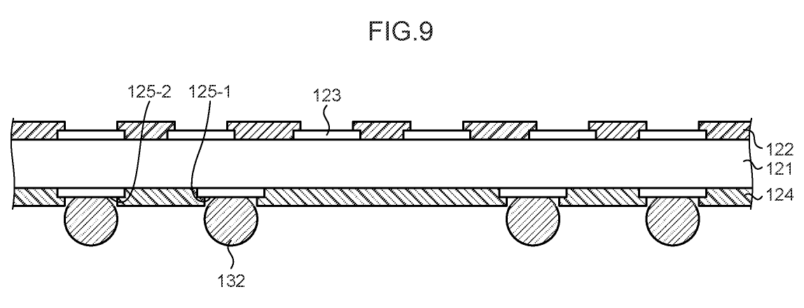

Through the process as described above, for example, as illustrated in FIG. 9, the solder balls 132 (one example of the second conductor ball) are bonded to the lower pads 125. With this configuration, the second wiring board 120 that forms an upper layer of the semiconductor device 100 is obtained. FIG. 9 is a diagram illustrating a specific example of a solder ball mounting process. In the obtained second wiring board 120, the solder balls 132 are bonded to the lower pads 125 that are exposed from the opening portions of the protective insulating layer 124. A diameter of each of the solder balls 132 may be set to, similarly to the solder balls 131, for example, about 100 μm to 250 μm. The solder balls 132 may have different diameters from the solder balls 131.

Meanwhile, it is preferable to manufacture the second wiring board 120 as an assembly in which the plurality of second wiring boards 120 are arrayed, instead of manufacturing the second wiring board 120 as a single unit. In the assembly, for example, the second wiring board 120 is manufactured in an individual section that is a divided grid.

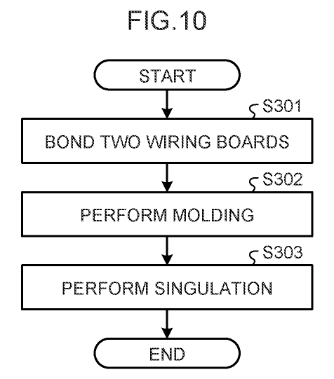

FIG. 10 is a flowchart illustrating the method of manufacturing the semiconductor device 100 according to one embodiment. The semiconductor device 100 is manufactured by using the first wiring board 110 and the second wiring board 120 as described above.

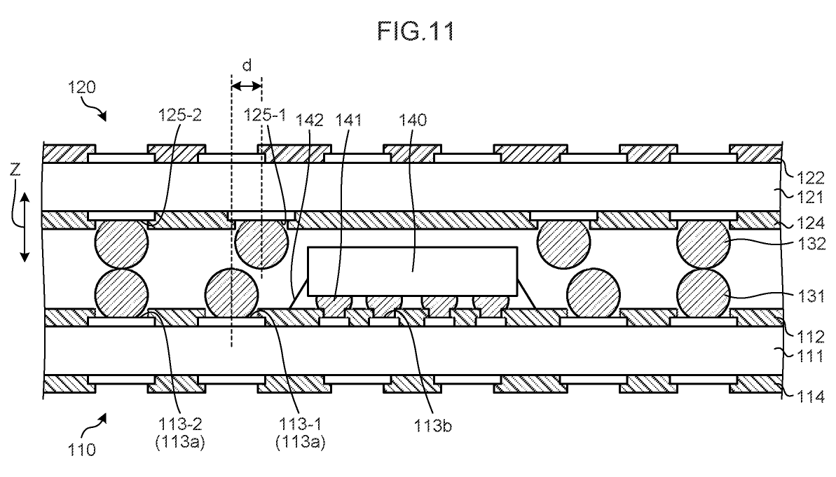

The first wiring board 110 and the second wiring board 120 are bonded together (Step S301). Firstly, for example, as illustrated in FIG. 11, the solder balls 132 that are bonded to the lower pads 125 of the second wiring board 120 are placed above the solder balls 131 that are bonded to the upper pads 113a of the first wiring board 110, and the second wiring board 120 is laminated on the first wiring board 110. FIG. 11 is a diagram for explaining lamination of the first wiring board 110 and the second wiring board 120. The electronic component 140 is placed between the first wiring board 110 and the second wiring board 120. The inner pad 125-1 of the second wiring board 120 is placed offset from the inner pad 113-1 of the first wiring board 110 in the direction that intersects the lamination direction Z. From the viewpoint of appropriately integrating the solder balls 131 and the solder balls 132, it is preferable that an offset amount d of the inner pad 125-1 of the second wiring board 120 with respect to the inner pad 113-1 of the first wiring board 110 is smaller than the diameter of each of the solder balls 131 or the solder balls 132. For example, the offset amount d may be set to about 1% to 10% of the diameter of each of the solder balls 131 or the solder balls 132. When the diameter of each of the solder balls 131 is different from the diameter of each of the solder balls 132, the offset amount d is adjusted based on the diameter of the larger solder ball.

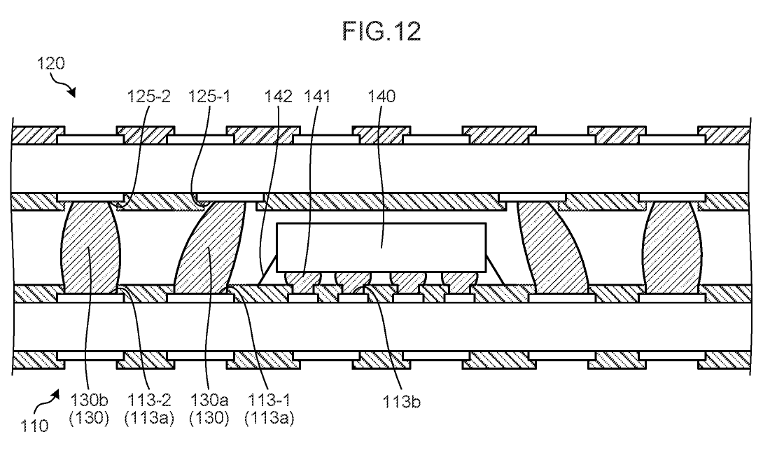

Subsequently, a reflow process is performed, so that the solder balls 131 and the solder balls 132 are melted and integrated, and the connection members 130 as integrated bodies are formed. Accordingly, for example, as illustrated in FIG. 12, the first wiring board 110 and the second wiring board 120 are bonded together by the plurality of connection members 130. In this case, because of the offset between the inner pad 125-1 and the inner pad 113-1, the drawing amount of the connection member 130a between the inner pad 125-1 and the inner pad 113-1 is increased as compared to the drawing amount of the connection member 130b between the outer pad 125-2 and the outer pad 113-2, so that it is possible to reduce the width of the connection member 130a. By reducing the width of the connection member 130a, a gap between the adjacent connection members 130a is increased. FIG. 12 is a diagram illustrating a specific example of a bonding process.

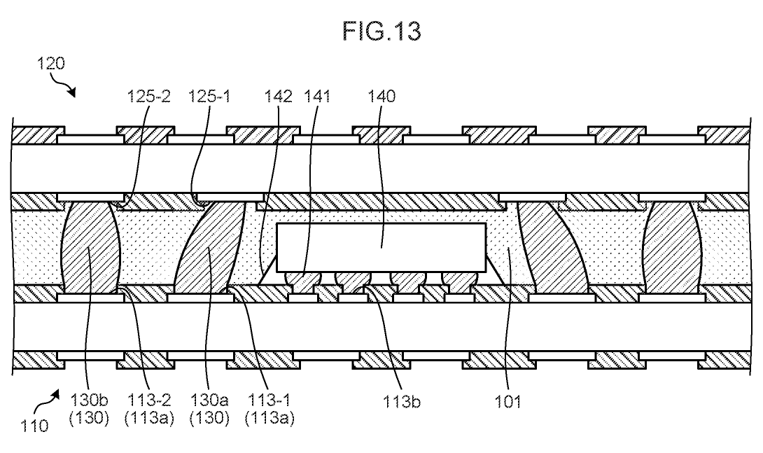

Further, for example, transfer molding is performed (Step S302), so that the space between the first wiring board 110 and the second wiring board 120 is filled with the sealing resin 101. In the transfer molding, the first wiring board 110 and the second wiring board 120 that are bonded together are placed in a mold, and the fluidized sealing resin 101 is injected into the mold. Furthermore, the sealing resin 101 is heated to predetermined temperature (for example, 175 degrees Celsius) and cured. Accordingly, for example, as illustrated in FIG. 13, the space between the first wiring board 110 and the second wiring board 120 is filled with the sealing resin 101, and the connection members 130 and the electronic component 140 are sealed. FIG. 13 is a diagram illustrating a specific example of a molding process. In this case, the gap between the adjacent connection members 130a is increased, so that the sealing resin 101 smoothly flows arround the electronic component 140. With this configuration, it is possible to allow the sealing resin 101 to smoothly flow into a relatively narrow space between the electronic component 140 and the first wiring board 110, so that it is possible to prevent occurrence of void in the sealing resin 101.

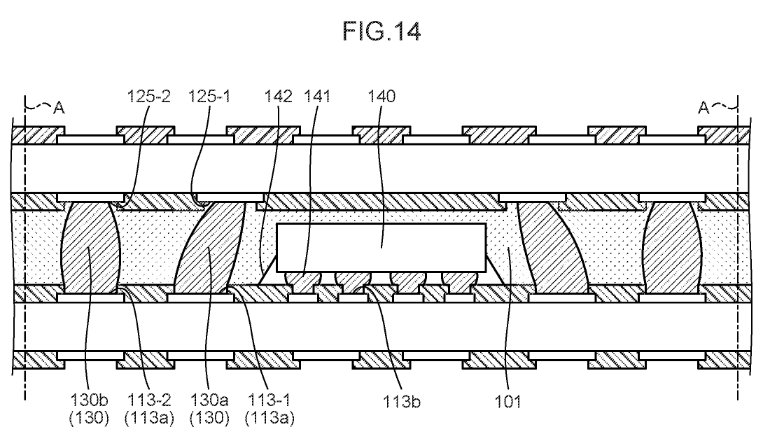

Through the process as described above, for example, as illustrated in FIG. 14, a structural body that has the same structure as the semiconductor device 100 is obtained. The structural body includes the assembly including the plurality of first wiring boards 110 and the assembly including the plurality of second wiring boards 120, so that singulation for cutting out each of the first wiring boards 110 and the second wiring boards 120 is performed (Step S303). FIG. 14 is a diagram illustrating a specific example of a singulation process. Specifically, by cutting the structural body illustrated in FIG. 14 at cutting lines A that are located on outer sides of the connection members 130b by, for example, a dicer or a slicer, so that the semiconductor device 100 is obtained.

### Modification

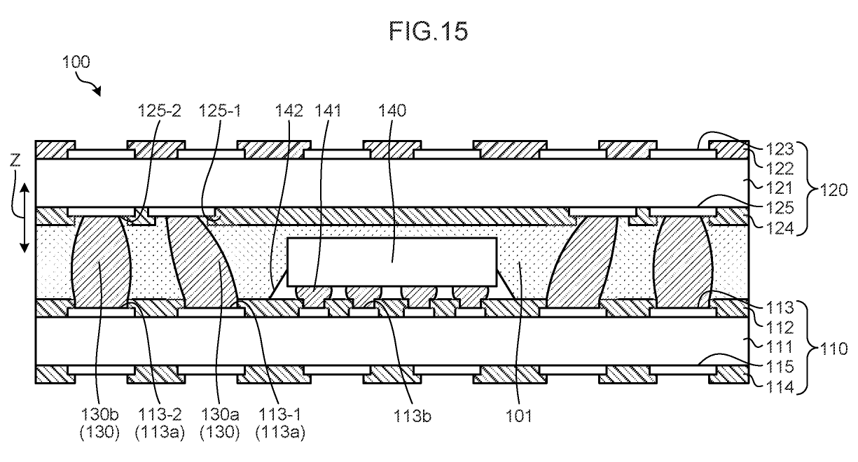

A modification of one embodiment will be described below with reference to FIG. 15. Meanwhile, in the modification described below, the same components as those of the above-described embodiment may be denoted by the same reference symbols, and repeated explanation may be omitted.

FIG. 15 is a diagram illustrating a configuration of the semiconductor device 100 according to the modification of one embodiment. FIG. 15 schematically illustrates a cross section of the semiconductor device 100. In the semiconductor device 100 according to the modification, placement of the inner pad 125-1 of the second wiring board 120 is different from the embodiment described above.

Specifically, in the modification, the inner pad 125-1 is placed offset from the inner pad 113-1 in a direction that intersects the lamination direction Z and that is away from the electronic component 140. With this configuration, it is possible to draw the connection member 130a in the direction that is away from the electronic component 140 between the inner pad 125-1 and the inner pad 113-1. Therefore, arround the electronic component 140, it is possible to boost flow of the sealing resin 101 to the electronic component 140, so that it is possible to further prevent occurrence of void in the sealing resin 101.

### Other Modifications

In the embodiment as described above, the example has been described in which the inner pad 125-1 that is connected to the connection member 130a arround the electronic component 140 is placed offset, but a component that is to be placed offset is not limited to the inner pad 125-1. Specifically, the outer pad 125-2 that is connected to the connection member 130b that is located farther from the electronic component 140 than the connection member 130a may be placed offset from the outer pad 113-2 in the direction that intersects the lamination direction Z.

As described above, a semiconductor device (as one example, the semiconductor device 100) according to one embodiment includes a first wiring board (as one example, the first wiring board 110), an electronic component (as one example, the electronic component 140), a second wiring board (as one example, the second wiring board 120), a plurality of connection members (as one example, the connection members 130), and a sealing resin (as one example, the sealing resin 101). The electronic component is mounted on the first wiring board. The second wiring board is laminated on the first wiring board so as to sandwich the electronic component. The plurality of connection members connect the first wiring board and the second wiring board. The sealing resin is filled in a space between the first wiring board and the second wiring board, and covers the electronic component and the plurality of connection members. The first wiring board includes a first pad (as one example, the inner pad 113-1) that is connected to a connection member (as one example, the connection member 130a) that is located arround the electronic component among the plurality of connection members. The second wiring board includes a second pad (as one example, the inner pad 125-1) that is connected to the connection member located arround the electronic component and that is placed offset from the first pad in a direction that intersects a lamination direction (as one example, the lamination direction Z) of the first wiring board and the second wiring board. With this configuration, it is possible to prevent occurrence of void.

Furthermore, the second pad may be placed offset from the first pad in a direction that intersects the lamination direction of the first wiring board and the second wiring board and that approaches the electronic component. With this configuration, it is possible to further prevent occurrence of void.

Moreover, the second pad may be placed offset from the first pad in a direction that intersects the lamination direction of the first wiring board and the second wiring board and that is away from the electronic component. With this configuration, it is possible to further prevent occurrence of void.

Furthermore, each of the connection members may be an integrated body in which a first conductor ball (as one example, the solder balls 131) that is mounted on the first wiring board and a second conductor ball (as one example, the solder balls 132) that is mounted on the second wiring board are integrated. An offset amount (as one example, the offset amount d) of the second pad with respect to the first pad may be smaller than a diameter of the first conductor ball or the second conductor ball. With this configuration, it is possible to appropriately integrate the first conductor ball and the second conductor ball.

Moreover, among the plurality of connection members, the connection member that is located arround the electronic component may have a smaller width than a different connection member (as one example, the connection member 130b) that is located farther from the electronic component than the connection member, in the direction that intersects the lamination direction. With this configuration, it is possible to prevent occurrence of void.

Furthermore, the first wiring board may include a first insulating layer (as one example, the protective insulating layer 112) that covers an upper surface of a base material (as one example, the substrate 111) of the first wiring board and that includes an opening portion (as one example, the opening portions 112a) for exposing the first pad. The second wiring board may include a second insulating layer (as one example, the protective insulating layer 124) that covers a lower surface of a base material (as one example, the substrate 121) of the second wiring board and that includes an opening portion (as one example, the opening portions 124a) for exposing the second pad. The opening portion of the second insulating layer may be placed offset from the opening portion of the first insulating layer in the direction that intersects the lamination direction of the first wiring board and the second wiring board. With this configuration, it is possible to keep an area of the second pad that is exposed from the opening portion of the second insulating layer to a certain area that is suitable for connection to the connection member that is located arround the electronic component.

According to one aspect of the semiconductor device disclosed in the present application, it is possible to prevent occurrence of void.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
a first wiring board;
an electronic component that is mounted on the first wiring board;
a second wiring board that is laminated on the first wiring board so as to sandwich the electronic component;
a plurality of connection members that connect the first wiring board and the second wiring board; and
a sealing resin that is filled in a space between the first wiring board and the second wiring board, and covers the electronic component and the plurality of connection members, wherein
the first wiring board includes
a first pad that is connected to a connection member that is located arround the electronic component among the plurality of connection members, and
the second wiring board includes
a second pad that is connected to the connection member located arround the electronic component and that is placed offset from the first pad in a direction that intersects a lamination direction of the first wiring board and the second wiring board.

2. The semiconductor device according to claim 1, wherein the second pad is placed offset from the first pad in a direction that intersects the lamination direction of the first wiring board and the second wiring board and that approaches the electronic component.

3. The semiconductor device according to claim 1, wherein the second pad is placed offset from the first pad in a direction that intersects the lamination direction of the first wiring board and the second wiring board and that is away from the electronic component.

4. The semiconductor device according to claim 1, wherein
each of the connection members is an integrated body in which a first conductor ball that is mounted on the first wiring board and a second conductor ball that is mounted on the second wiring board are integrated, and
an offset amount of the second pad with respect to the first pad is smaller than a diameter of one of the first conductor ball and the second conductor ball.

5. The semiconductor device according to claim 1, wherein among the plurality of connection members, the connection member that is located arround the electronic component has a smaller width than a different connection member that is located farther from the electronic component than the connection member, in the direction that intersects the lamination direction.

6. The semiconductor device according to claim 1, wherein an underfill material is arranged between the first wiring board and the electronic component.

7. The semiconductor device according to claim 1, wherein
the first wiring board includes
a first insulating layer that covers an upper surface of a base material of the first wiring board and that includes an opening portion for exposing the first pad,
the second wiring board includes
a second insulating layer that covers a lower surface of a base material of the second wiring board and that includes an opening portion for exposing the second pad, and
the opening portion of the second insulating layer is placed offset from the opening portion of the first insulating layer in the direction that intersects the lamination direction of the first wiring board and the second wiring board.
